(19) United States
(12) Patent Application Publication
(10) Pub. No.: US 2026/0141931 A1
(43) Pub. Date: May 21, 2026

(54) VOLTAGE GENERATOR, MEMORY DEVICE INCLUDING THE SAME, AND OPERATING METHOD OF MEMORY DEVICE

(71) Applicant: Samsung Electronics Co., Ltd., Suwon-si (KR)

(72) Inventor: Jeil Ryu, Suwon-si (KR)

(21) Appl. No.: 19/349,998

(22) Filed: Oct. 4, 2025

(30) Foreign Application Priority Data
Nov. 21, 2024 (KR) 10-2024-0167748

(51) Int. Cl. G11C 5/14

(52) U.S. Cl. CPC G11C 5/147; G11C 5/145

(57) ABSTRACT

A memory device includes a memory cell region in which a plurality of memory cells electrically connected to a plurality of word lines are arranged, and a peripheral circuit region in which peripheral circuits configured to control the plurality of memory cells are arranged. The peripheral circuit region includes a voltage generator configured to generate an operating voltage applied to the plurality of word lines. The voltage generator includes a regulator configured to adjust and output a first output voltage having a first level on a first node, a sub-voltage generating circuit configured to generate the operating voltage on an output node based on the first output voltage, and a monitoring circuit configured to monitor the first output voltage, and control the sub-voltage generating circuit based on a result of the monitoring.

### CROSS-REFERENCE TO RELATED APPLICATION(S)

This application is based on and claims priority under 35 USC §119 to Korean Patent Application No. 10-2024-0167748 filed on Nov. 21, 2024, in the Korean Intellectual Property Office, the disclosure of which is incorporated by reference herein in its entirety.

### BACKGROUND

The inventive concept relates to a voltage generator, a memory device including the voltage generator, and an operating method of the memory device. More particularly, the inventive concept relates to a voltage generator capable of monitoring an output voltage of a regulator and, based on the monitored output voltage, controlling a sub-voltage generating circuit.

Memory devices are storage devices that may store data and read the data when needed. Memory devices may be broadly divided into nonvolatile memory (NVM) in which stored data does not disappear even when power is not supplied and volatile memory (VM), in which stored data disappears when power is not supplied.

Memory devices may have various wiring arrangements placed and used therein to control a plurality of memory cells arranged therein. Examples of such wirings may include word lines and bit lines that connect to memory cells. A word line voltage may be applied to a word line, and the word line voltage may be generated by a voltage generator and transferred to the word line through a row decoder. A delay in a setup time of the word line voltage may increase the overall operating time of the memory device and thus, a method for reducing the setup time of the word line voltage may be needed.

### SUMMARY

The inventive concept provides a voltage generator capable of reducing a setup time of a word line and also reducing the amount of driving current.

According to an aspect of the inventive concept, a memory device includes a memory cell region in which a plurality of memory cells electrically connected to a plurality of word lines are arranged, and a peripheral circuit region in which peripheral circuits configured to control the plurality of memory cells are arranged. The peripheral circuit region includes a voltage generator configured to generate an operating voltage applied to the plurality of word lines to operate the memory cell. The voltage generator includes a regulator configured to adjust and output a first output voltage having a first level on a first node, a sub-voltage generating circuit configured to generate the operating voltage on an output node based on the first output voltage, and a monitoring circuit configured to monitor the first output voltage and control the sub-voltage generating circuit based on a monitoring result based on a result of the monitoring.

According to another aspect of the inventive concept, a voltage generator includes a regulator configured to generate a first output voltage having a first level that is adjusted, a sub-voltage generating circuit configured to generate an operating voltage based on the first output voltage based on the first output voltage, and a monitoring circuit configured to monitor a voltage level of the first output voltage and control the sub-voltage generating circuit based on a result of the monitoring. The sub-voltage generating circuit is configured to operate in one of a first operating mode and a second operating mode different from the first operating mode based on the voltage level of the first output voltage.

According to another aspect of the inventive concept, an operating method of a memory device including a memory cell array having a plurality of memory cells connected to a plurality of word lines, a regulator configured to generate a first output voltage having a first level that is adjusted, and a sub-voltage generating circuit including a current generating circuit and a feedback loop circuit and configured to generate an operating voltage applied to the plurality of word lines based on the first output voltage, the operating method includes monitoring the first output voltage adjusted by the regulator, determining whether the monitored voltage drops, determining an operating mode of the sub-voltage generating circuit based on a voltage range of the monitored voltage, and outputting the operating voltage from the current generating circuit to the plurality of word lines based on the first output voltage. The voltage range is between the first level and a drop level lower than the first level.

### BRIEF DESCRIPTION OF THE DRAWINGS

Embodiments will be more clearly understood from the following detailed description taken in conjunction with the accompanying drawings in which:

FIG. 1 is a block diagram illustrating a nonvolatile memory system according to an embodiment;

FIG. 2 is a block diagram illustrating a nonvolatile memory device according to an embodiment;

FIG. 3 is a block diagram illustrating a configuration of a voltage generator according to an embodiment;

FIG. 4 is a block diagram illustrating a configuration of a voltage generator according to an embodiment;

FIG. 5 is a diagram illustrating an example of a sub-voltage generating circuit and a load circuit, according to an embodiment;

FIG. 6A illustrates a graph of a first output voltage and a second output voltage over time;

FIG. 6B illustrates a graph of a second output voltage over time according to differently controlling a sub-voltage generating circuit depending on a section of the first output voltage;

FIG. 7 is a diagram illustrating a current flow in a sub-voltage generating circuit according to a first operating mode;

FIG. 8 is a diagram illustrating a current flow in a sub-voltage generating circuit according to a second operating mode;

FIG. 9 illustrates a circuit of a voltage generator according to an embodiment;

FIG. 10 illustrates a circuit of a voltage generator according to an embodiment;

FIG. 11 illustrates a circuit of a voltage generator according to an embodiment; and

FIG. 12 is a flowchart illustrating an operating method of a memory device according to an embodiment.

### DETAILED DESCRIPTION OF THE EMBODIMENTS

Hereinafter, various embodiments are described with reference to the accompanying drawings.

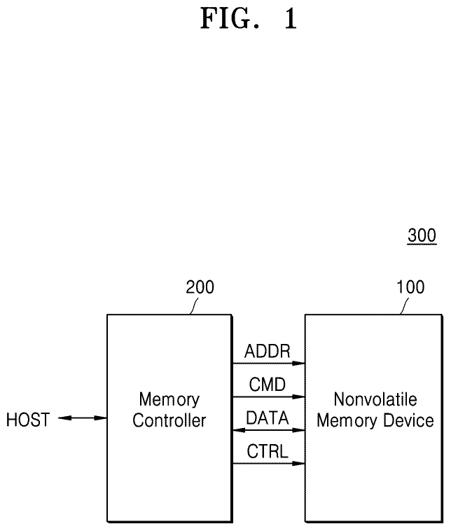

FIG. 1 is a block diagram illustrating a nonvolatile memory system according to an embodiment.

Referring to FIG. 1, a nonvolatile memory system 300 may include a memory controller 200 and a nonvolatile memory device 100. Examples of the nonvolatile memory system 300 illustrated in FIG. 1 may include a data storage medium based on flash memory, such as memory cards, USB memory, and solid state drives (SSD), but the embodiments are not limited to these examples.

The memory controller 200 may be connected to a host and the nonvolatile memory device 100. The memory controller 200 may be configured to access the nonvolatile memory device 100 in response to a request from the host, as illustrated. The memory controller 200 may be configured to provide an interface between the nonvolatile memory device 100 and the host. In addition, the memory controller 200 may be configured to drive firmware for controlling the nonvolatile memory device 100.

The memory controller 200 may control operation of the nonvolatile memory device 100. In detail, the memory controller 200 may provide a command CMD, an address ADDR, a control signal CTRL, and data DATA along input/output lines connected to the nonvolatile memory device 100.

The control signal CTRL provided from the memory controller 200 to the nonvolatile memory device 100 may include, for example, chip enable CE, write enable WE, and read enable RE, but the embodiments are not limited thereto.

The memory controller 200 and the nonvolatile memory device 100 may each be provided as one chip, one package, or one module. Alternatively, the memory controller 200 and the nonvolatile memory device 100 may be mounted using packages, such as, a package on package (PoP), ball grid arrays (BGA), chip scale packages (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flatpack (TQFP), small outline (SOIC), shrink small outline package (SSOP), thin small outline (TSOP), thin quad flatpack (TQFP), system in package (SIP), multichip package (MCP), wafer-level fabricated package (WFP), wafer-level processed stack package (WSP), etc.

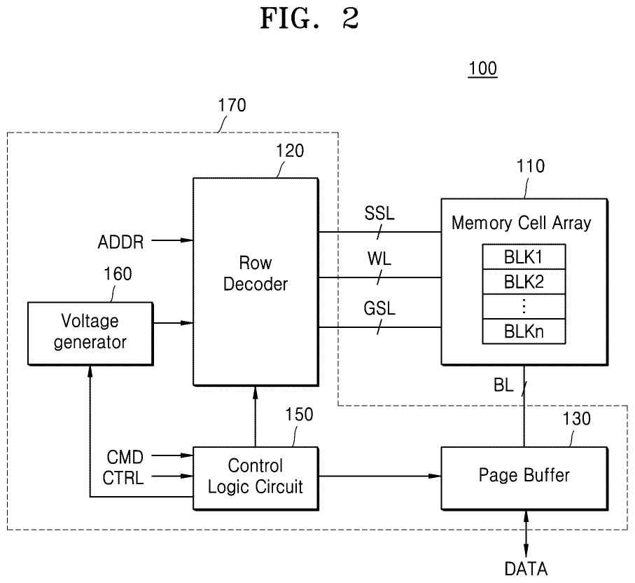

Hereinafter, the configuration of the nonvolatile memory device 100 is described in more detail with reference to FIG. 2.

FIG. 2 is a block diagram illustrating the nonvolatile memory device 100 according to an embodiment.

Referring to FIG. 2, the nonvolatile memory device 100 according to an embodiment may include a memory cell array region 110 and a peripheral circuit region 170.

The memory cell array region 110 may include a plurality of memory cell blocks BLK1 to BLKn, n may be a natural number equal to or greater than 2. Each of the memory cell blocks BLK1 to BLKn may include a plurality of memory cells. The memory cell blocks BLK1 to BLKn may be connected to the peripheral circuit region 170 via bit lines BL, word lines WL, at least one string select line SSL, and at least one ground select line GSL. In detail, the memory cell blocks BLK1 to BLKn may be connected to a row decoder 120 via word lines WL, at least one string select line SSL, and at least one ground select line GSL. In addition, the memory cell blocks BLK1 to BLKn may be connected to a page buffer 130 via bit lines BL.

The peripheral circuit region 170 may receive the address ADDR, the command CMD, and the control signal CTRL from the outside of the nonvolatile memory device 100 and may transmit and receive data DATA to and from an external device of the nonvolatile memory device 100. The peripheral circuit region 170 may include a control logic circuit 150, the row decoder 120, the page buffer 130, and a voltage generator 160 that generates various voltages required for operation.

Although not shown, the peripheral circuit region 170 may further include various sub-circuits, such as an input/output circuit, an error correction circuit for correcting errors in data DATA read from the memory cell array region 110 of the nonvolatile memory device 100, etc.

The control logic circuit 150 may be connected to the row decoder 120, the voltage generator 160, and the input/output circuit (not shown). The control logic circuit 150 may control the overall operation of the nonvolatile memory device 100. The control logic circuit 150 may generate various internal control signals used within the nonvolatile memory device 100 in response to the control signal CTRL.

For example, the control logic circuit 150 may adjust a voltage level provided to the word lines WL and bit lines BL when performing a memory operation, such as a program operation or an erase operation.

The row decoder 120 may select at least one of the memory cell blocks BLK1 to BLKn in response to the address ADDR and may select at least one word line WL, at least one string select line SSL, and at least one ground select line GSL of the selected memory cell blocks BLK1 to BLKn. The row decoder 120 may transmit a voltage for performing a memory operation to a selected word line WL of the selected memory cell blocks BLK1 to BLKn.

The page buffer 130 may be connected to the memory cell array region 110 via bit lines BL. The page buffer 130 may act as a writer driver or a sense amplifier. In detail, during a program operation, the page buffer 130 may operate as a write driver to apply voltage according to the data DATA to be stored in the memory cell array region 110 to the bit lines BL. Meanwhile, during a read operation, the page buffer 130 may operate as a sense amplifier to detect the data DATA stored in the memory cell array region 110.

The voltage generator 160 may generate a voltage supplied to a memory cell array region 110. The voltage generator 160 may generate various types of internal voltages for performing program, read, and erase operations on the memory cell array region 110 based on a control signal received from the control logic circuit 150. For example, the voltage generator 160 may generate a word line voltage, a program voltage, a read voltage, a pass voltage, an erase verify voltage, or a program verify voltage. In addition, the voltage generator 160 may further generate a string selection line voltage and a ground selection line voltage based on the control signal. In addition, the voltage generator 160 may further generate a bit line voltage based on the control signal.

According to an example, the voltage generator 160 may further include a regulator. The regulator may adjust a voltage supplied to the regulator to generate at least one internal voltage. As an example, the voltage supplied to the regulator may be a voltage generated by a charge pump. The voltage generator 160 according to an embodiment may further include a monitoring circuit capable of monitoring the voltage adjusted by the regulator in real time. Through the monitoring circuit, whether the adjusted voltage level drops may be monitored, and switches included in a sub-voltage generating circuit connected to the regulator may be controlled during a period from when the voltage drop occurs to when the dropped voltage is recovered. Through this, a fast rising of an output of the sub-voltage generating circuit may be induced, thereby reducing a driving current of the charge pump connected to the regulator, which may be efficient in terms of power. A configuration and operating method of the voltage generator 160 are described in more detail below.

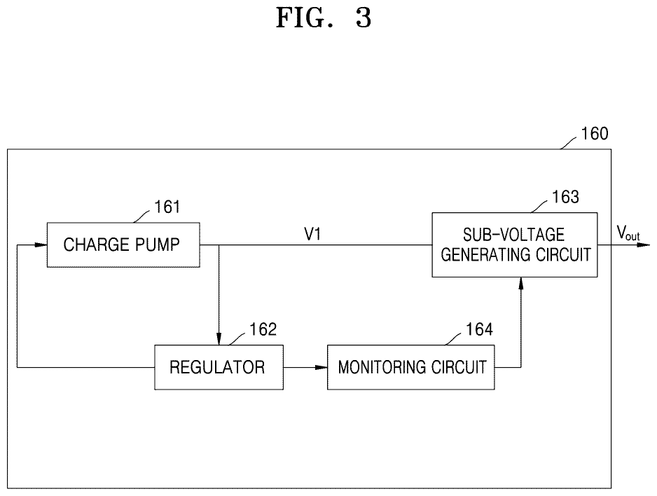

FIG. 3 is a block diagram illustrating a configuration of the voltage generator 160 according to an embodiment.

Referring to FIG. 3, the voltage generator 160 may include a charge pump 161, a regulator 162, a sub-voltage generating circuit 163, and a monitoring circuit 164.

The charge pump 161 may include a plurality of charge pump circuits and a control circuit. Each of the charge pump circuits may be enabled or disabled by the control circuit and perform a charge pumping operation using a power supply voltage and a pumping clock signal provided from a clock generator (not shown). According to an embodiment, the charge pump 161 may be positioned outside the voltage generator 160.

The regulator 162 may be connected to an output node of the charge pump 161. The regulator 162 may regulate a pumping voltage signal output from the charge pump 161 to generate a first output voltage V1, which is a regulated voltage, and may transmit the first output voltage V1 to the memory cell array (110 in FIG. 2) through the sub-voltage generating circuit 163 and the row decoder (120 in FIG. 2). According to an example, the regulator 162 may adjust a level of the first output voltage V1 to a target level. As an example, the regulator 162 may include, but is not limited to, a circuit configuration, such as a linear regulator or a low dropout (LDO).

The sub-voltage generating circuit 163 may receive the first output voltage V1 adjusted by the regulator 162 and generate a lower voltage based thereon. In the embodiment of FIG. 3, one sub-voltage generating circuit 163 is provided, but according to an embodiment, a plurality of sub-voltage generating circuits 163 may be provided. The sub-voltage generating circuit 163 may generate a second output voltage Vout which is a lower voltage of the first output voltage V1, and the generated second output voltage may be transmitted to the memory cell array (110 in FIG. 2) through the row decoder (120 in FIG. 2). As an example, the second output voltage Vout may be an operating voltage for operating a word line. For example, the operating voltage for operating a word line may be referred to as the word line voltage.

The monitoring circuit 164 may monitor the first output voltage V1 that is adjusted and output by the regulator 162. The monitoring circuit 164 may monitor the first output voltage V1 adjusted and output by the regulator 162 and may control some switches included in the sub-voltage generating circuit 163 based on the result. The monitoring circuit 164 may monitor whether the first output voltage V1 drops and/or a drop occurrence period, and if drop occurs, the monitoring circuit 164 may control some switches included in the sub-voltage generating circuit 163 to one of a first operating mode or a second operating mode during a period until drop is recovered. As an example, the first operating mode may be a mode in which a feedback loop included in the sub-voltage generating circuit 163 operates perfectly. As an example, the second operating mode may be a mode in which the feedback loop included in the sub-voltage generating circuit 163 does not operate perfectly. The monitoring circuit 164 according to the inventive concept may monitor the first output voltage V1 output from the regulator 162, and if drop occurs in the first output voltage V1, the monitoring circuit 164 may increase a rising rate of the second output voltage Vout of the sub-voltage generating circuit 163 and reduce the driving current by controlling switches included in the sub-voltage generating circuit 163 to one of the first operating mode or the second operating mode.

As an example, there may be a load circuit connected to the voltage generator 160, and when the load circuit is connected, drop may occur in the first output voltage V1. Herein, when the level of the first output voltage V1 falls below a certain level, the switches may be controlled to operate in the second operating mode in which the feedback loop is turned off. In the second operating mode, the second output voltage is controlled to rise to have the same rate as a rising rate based on an output voltage from the regulator 162 by turning off the feedback loop, and when the level of the first output voltage V1 rises to reach or above the certain level, the feedback loop is operated again, thereby ensuring a fast rising rate and also saving the power of the voltage generator.

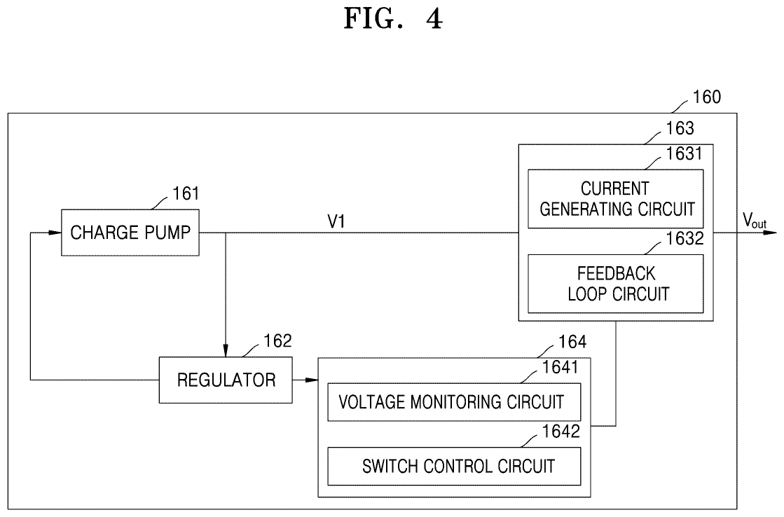

FIG. 4 is a block diagram illustrating a configuration of the voltage generator 160 according to an embodiment.

In the description of FIG. 4, description of the same components as those described above with reference to FIG. 3 is omitted.

The voltage generator 160 of FIG. 4 may include the charge pump 161, the regulator 162, the sub-voltage generating circuit 163, and the monitoring circuit 164. The configurations of the charge pump 161 and regulator 162 are the same as those described above with reference to FIG. 3, so description is omitted.

The sub-voltage generating circuit 163 may include a current generating circuit 1631 and a feedback loop circuit 1632. The current generating circuit 1631 may include a current source and may be a circuit capable of generating a current flowing inside the sub-voltage generating circuit 163 or copying a current (e.g., a source current) generated by the current source. As an example, the current generating circuit 1631 may include a current mirror circuit. The feedback loop circuit 1632 may be a circuit configured to form a feedback loop within the sub-voltage generating circuit 163. According to an example, the sub-voltage generating circuit 163 may perfectly operate the feedback loop circuit 1632 based on the current generating circuit 1631. Each of the current generating circuit 1631 and the feedback loop circuit 1632 may include a plurality of switches, and whether the feedback loop circuit 1632 may perfectly operate may be determined based on the control of the switches. In example embodiments, each of the plurality of switches may include a P-type metal-oxide-semiconductor (PMOS) transistor or an N-type MOS (NMOS) transistor.

The monitoring circuit 164 may include a voltage monitoring circuit 1641 and a switch control circuit 1642. The voltage monitoring circuit 1641 may monitor the first output voltage V1. The voltage monitoring circuit 1641 may monitor whether drop occurs in the first output voltage V1 beyond a set value and, if drop occurs, the voltage monitoring circuit 1641 may transmit a control signal to the switch control circuit 1642. The switch control circuit 1642 may control whether to turn on or off the switches included in the current generating circuit 1631 and the feedback loop circuit 1632 based on the transmitted control signal. Under control by the switch control circuit 1642, the sub-voltage generating circuit 163 may operate in one of the first operating mode or the second operating mode. The first operating mode may be a mode in which the feedback loop of the sub-voltage generating circuit 163 operates perfectly, and the second operating mode may be a mode in which the feedback loop of the sub-voltage generating circuit 163 does not operate perfectly. The switch control circuit 1642 may control the turn-on and turn-off of the switches differently in each mode to control each of the first operating mode and the second operating mode.

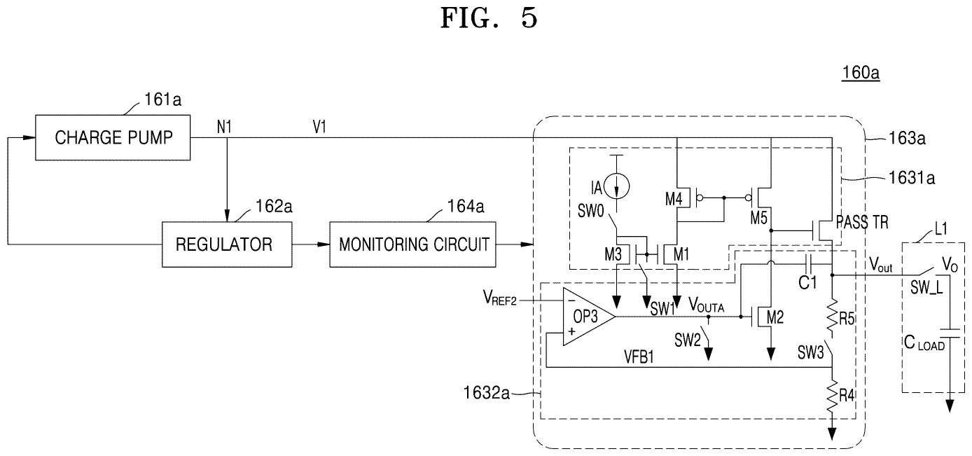

FIG. 5 is a diagram illustrating a configuration of a sub-voltage generating circuit among the components of a voltage generator according to an embodiment.

A voltage generator 160a of FIG. 5 may include a charge pump 161a, a regulator 162a, a sub-voltage generating circuit 163a, and a monitoring circuit 164a. The configuration of the charge pump 161a, the regulator 162a, the sub-voltage generating circuit 163a, and the monitoring circuit 164a corresponds to the configuration of the charge pump 161, the regulator 162, the sub-voltage generating circuit 163, and the monitoring circuit 164 described above with reference to FIGS. 3 and 4, and therefore, a redundant description thereof is omitted.

The sub-voltage generating circuit 163a of FIG. 5 may include a current generating circuit 1631a and a feedback loop circuit 1632a.

The current generating circuit 1631a may include a current source IA, a first switch SW0 connected in series with the current source IA, a third transistor M3, a first transistor M1, a second switch SW1, a fourth transistor M4, a fifth transistor M5, and a pass transistor PASS TR.

As an example, the third transistor M3 and the first transistor M1 may be NMOS transistors. A gate of the third transistor M3 may be connected to a gate of the first transistor M1. A first end of the third transistor M3 may be connected to the current source IA through the first switch SW0. The first end of the third transistor M3 may be connected to the gate of the third transistor M3. A second end of the third transistor M3 and a second end of the first transistor M1 may be connected to a ground. The third transistor M3 and the first transistor M1 may form a current mirror circuit so that the current generated from the current source IA may be copied and flow in the same manner to the first transistor M1. The second switch SW1 may be connected to the gates of the third transistor M3 and the first transistor M1.

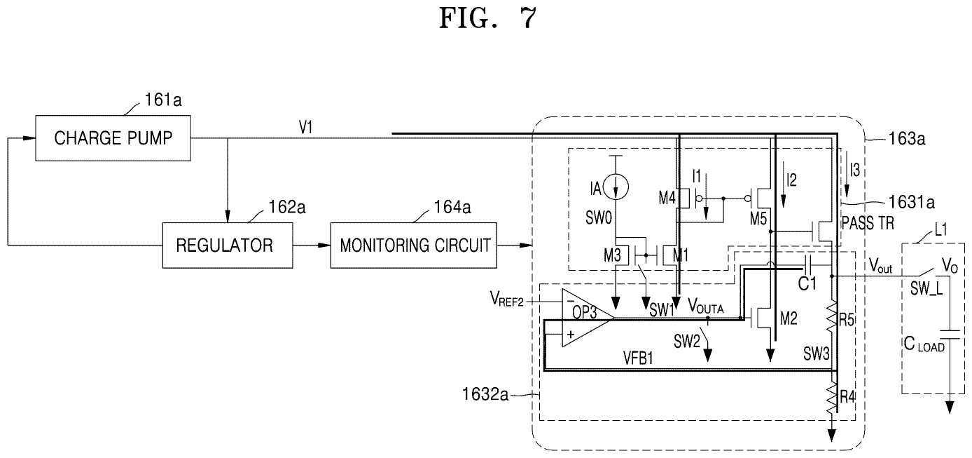

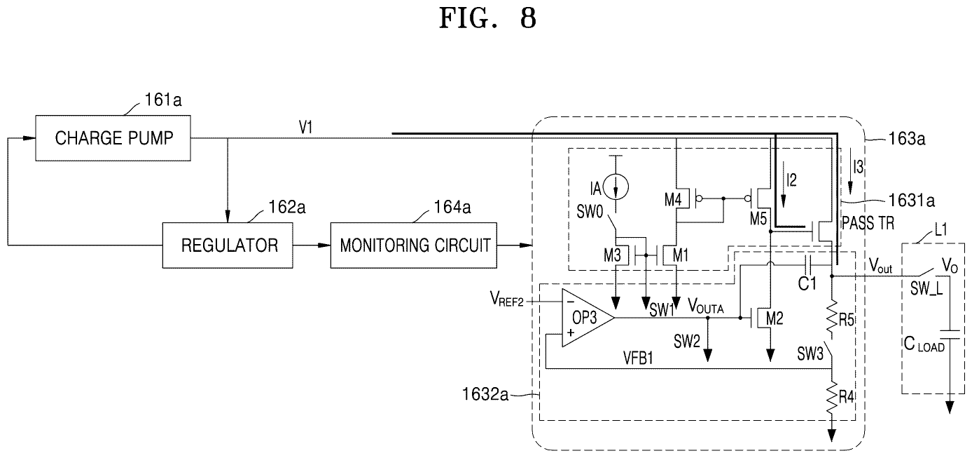

The current generating circuit 1631a may include the first switch SW0 and the second switch SW1. Depending on whether the first switch SW0 is turned on, it may be determined whether the current generated by the current source IA is transmitted to the third transistor M3. Depending on whether the second switch SW1 is turned on, it may be determined whether the current generated by the current source IA may be copied and flow to the first transistor M1. The operation of the sub-voltage generating circuit 163a according to the turn-on of each of the first switch SW0 and the second switch SW1 is described below with reference to FIGS. 7 and 8.

As an example, the fourth transistor M4 and the fifth transistor M5 may be PMOS transistors. A gate of the fourth transistor M4 may be connected to a gate of the fifth transistor M5. A first end of the fourth transistor M4 may be connected to a first end of the first transistor M1. The first end of the fourth transistor M4 may be connected to the gate of the fourth transistor M4. A second end of each of the fourth, fifth, and pass transistors M4, M5, and PASS TR may be connected to a first node N1 that outputs the first output voltage V1. The fourth transistor M4 and the fifth transistor M5 may form a current mirror circuit so that the current flowing in the first transistor M1 may be copied and flow in the same manner to the fifth transistor M5.

As an example, a first end of the fifth transistor M5 may be connected to a gate of the pass transistor PASS TR. A first end of the pass transistor PASS TR may be connected to an output node of the sub-voltage generating circuit 163a. When current flows through the fifth transistor M5, the pass transistor PASS TR may be turned on, so that the current generated by the current source IA may be copied and flow to the pass transistor PASS TR, which may be transmitted to an output node of the sub-voltage generating circuit 163a. For example, the pass transistor PASS TR may output the second output voltage Vout based on the current flowing through the fifth transistor M5.

The feedback loop circuit 1632a may include a third comparator OP3, a third switch SW2, a second transistor M2, a first capacitor C1, a fourth switch SW3, a fourth resistor R4, and a fifth resistor R5.

The second transistor M2 may be an NMOS transistor. A first end of the second transistor M2 may be connected to the first end of the fifth transistor M5 and a second end of the second transistor M2 may be connected to the ground. A gate of the second transistor M2 may be connected to a first end of the first capacitor C1. The gate of the second transistor M2 may be connected to an output of the third comparator OP3. The third switch SW2 may be connected to the gate of the second transistor M2. The fifth resistor R5 may be connected to a second end of the first capacitor C1. The fourth switch SW3 may be connected between the fifth resistor R5 and the fourth resistor R4. For example, when the fourth switch SW3 is turned on the fifth resistor R5 and the fourth resistor R4 may be connected to each other. A second reference voltage V_{REF2} may be input to an inverting input of the third comparator OP3, and a feedback voltage VFB1 output from a node between the fifth resistor R5 and the fourth resistor R4 may be input to a non-inverting input of the third comparator OP3. For example, the feedback voltage VFB1 may be output to the third comparator OP3 when the fourth switch SW3 is turned on.

In the feedback loop circuit 1632a, the feedback voltage VFB1 based on the fourth resistor R4 and the fifth resistor R5 may be compared with the second reference voltage V_{REF2} through the third comparator OP3, and a result may be output, and the turn-on of the second transistor M2 may be controlled according to the result, and the first capacitor C1 may be charged and controlled to output a constant voltage.

The feedback loop circuit 1632a may include the third switch SW2 and the fourth switch SW3, and whether the loop of the feedback loop circuit 1632a is perfectly formed may be determined depending on whether the third switch SW2 and the fourth switch SW3 are turned on. When the third switch SW2 is turned on, the output from the third comparator OP3 may flow through a path generated by the turn-on of the third switch SW2, and the feedback loop may not be formed perfectly. When the fourth switch SW3 is turned on, the fourth resistor R4 and the fifth resistor R5 may be electrically connected, so that the feedback voltage VFB1 may be transmitted to the third comparator OP3.

As an example, when the third switch SW2 is turned off and the fourth switch SW3 is turned on, a perfect feedback loop of the feedback loop circuit 1632a may be formed. As an example, when the third switch SW2 is turned on and the fourth switch SW3 is turned off, the feedback loop circuit 1632a may not form a perfect feedback loop.

As an example, the first switch SW0 and the fourth switch SW3 may be switches that may control the current generating circuit and the feedback loop circuit to operate normally through turn-on of the switches, and the second switch SW1 and the third switch SW2 may be switches that may control the current generating circuit and the feedback loop circuit to not operate normally through turn-on of the switches. In this manner, it is possible to control whether the feedback loop of the feedback loop circuit 1632a is perfectly formed by controlling the first switch SW0, the second switch SW1, the third switch SW2, and the fourth switch SW3 included in the sub-voltage generating circuit 163a, and accordingly, the operating mode of the sub-voltage generating circuit 163a may be determined.

For example, in the first operating mode, the current generating circuit 1631a may generate and copy the current and output the operating voltage and the feedback loop circuit 1632a may operate (or activate) based on the operating voltage when the first switch SW0 and the fourth switch SW3 are turned on and the second switch SW1 and the third switch SW2 are turned off. In the second operating mode, the current generating circuit 1631a may output the operating voltage and the feedback loop circuit 1632a may not operate (or inactivate) when the first switch SW0 and the fourth switch SW3 are turned off and the second switch SW1 and the third switch SW2 are turned on.

Referring to FIG. 5, a load circuit L1 may be additionally connected to the output node of the sub-voltage generating circuit 163a. The load circuit L1 may include a fifth switch SW_L and a load capacitor C_{LOAD} connected between the fifth switch SW_L and the ground. Herein, the fifth switch SW_L may be a block word line switch and a node connected to the fifth switch SW_L and the load capacitor C_{LOAD} may be connected to a word line. When the fifth switch SW_L is turned on (e.g., a block word line switch is selected), the load capacitor C_{LOAD} may be connected to the second output voltage Vout, and drop from the first output voltage V1 and the second output voltage Vout may occur during the process of charging the load capacitor C_{LOAD}. Herein, in order to reduce the time for recovery from drop of the second output voltage Vout, the sub-voltage generating circuit 163a may be controlled in the first operating mode or the second operating mode according to a voltage range of the first output voltage V1, and accordingly, the recovery time of the second output voltage Vout may be reduced, thereby enabling saving of driving current. Details thereof are described in more detail with reference to the drawings below.

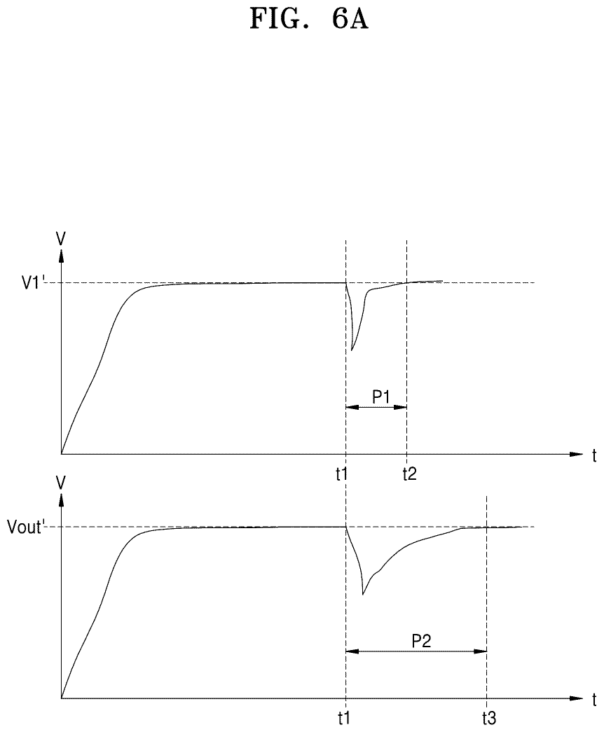

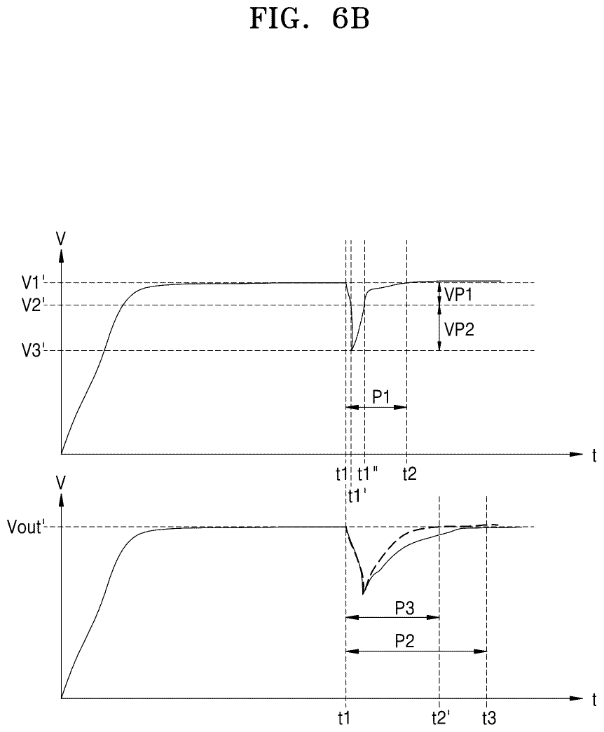

FIG. 6A illustrates a graph of a first output voltage and a second output voltage over time.

Referring to FIG. 6A, the graph of the first output voltage V1 over time and the graph of the second output voltage Vout over time are shown. The horizontal axis of the graph may represent time, and the vertical axis may represent voltage level. The upper drawing in FIG. 6A is a graph of the first output voltage V1 over time, and the lower drawing in FIG. 6A is a graph of the second output voltage Vout over time.

The first output voltage V1 may be a voltage output by adjusting the output of the charge pump 161 of FIG. 5 by the regulator 162. As described above, when the fifth switch SW_L connected to the load circuit L1 is turned on, the sub-voltage generating circuit 163 may be connected to the load capacitor C_{LOAD}, and the first output voltage V1 may temporarily drop to charge the load capacitor C_{LOAD}.

Referring to FIG. 6A, the fifth switch SW_L may be turned off before a first point in time t1, and thus may not be connected to the load capacitor C_{LOAD}. Therefore, until the first point in time t1, the first output voltage V1 may maintain a voltage level V1′ adjusted by the regulator 162. When the fifth switch SW_L is turned on at the first point in time t1, the sub-voltage generating circuit 163 may be connected to the load circuit L1, and accordingly, drop may occur in the first output voltage V1 during the process of charging the load capacitor C_{LOAD}. The voltage drop that has occurred may be gradually recovered over a period of time P1 and return to the adjusted voltage level V1′ at a second point in time t2.

Referring to the lower drawing in FIG. 6A, for the second output voltage Vout, the fifth switch SW_L may be turned off before the first point in time t1, and thus may not be connected to the load capacitor C_{LOAD}. Therefore, until the first point in time t1, the second output voltage V2 may maintain the output voltage level Vout'. When the fifth switch SW_L is turned on at the first point in time t1, the sub-voltage generating circuit 163 may be connected to the load circuit L1, and accordingly, a voltage level of the second output voltage Vout may also drop. The voltage drop that has occurred may be gradually recovered over a period of time P2 and return to the output voltage level Vout′ at a third point in time t3. Herein, for convenience of description, the time taken for the voltage level to return to the original voltage level after the voltage drop occurs is referred to as a recovery time. As described, the recovery time of the first output voltage V1 may be the period of time P1, and the recovery time of the second output voltage Vout may be the period of time P2.

Here, because the second output voltage Vout is closely related to the voltage applied to the word line, as the recovery time of the second output voltage Vout becomes longer, a setup time of the word line may also be delayed, and accordingly, an overall operation time may become longer. To reduce the recovery time of the second output voltage Vout, a rising rate has to be fast, which requires supplying additional power. Here, if additional power is supplied by increasing the amount of current inside the feedback loop included in the sub-voltage generating circuit, the amount of current output from the charge pump may increase, which may be inefficient as power consumption increases.

Herein, a voltage generator capable of reducing the recovery time of the second output voltage Vout without increasing the current flowing in the feedback loop of the sub-voltage generating circuit is provided.

FIG. 6B illustrates a graph of the second output voltage over time according to differently controlling the sub-voltage generating circuit depending on a section of the first output voltage.

In the drawing of FIG. 6B, the same description as that given above with reference to FIG. 6A may be omitted. The upper drawing in FIG. 6B is a graph of the first output voltage V1 over time, and the lower drawing in FIG. 6B is a graph of the second output voltage Vout over time. As an example, the upper drawing in FIG. 6B may coincide with the upper drawing of FIG. 6A, and a portion indicated by the solid line in the lower drawing of FIG. 6B may coincide with the lower drawing of FIG. 6A.

Referring to FIG. 6B, a voltage range from an adjusted voltage level V1′ to a drop voltage level V3′ may be a range in which the first output voltage V1 drops. For example, the voltage level V3′ may be the minimum voltage level after the first output voltage V1 drops and before the first output voltage V1 recovers. Referring to FIG. 6B, the recovery time P1 of the first output voltage V1 may be a time interval between the first point in time t1 and the second point in time t2. As an example, the recovery time P1 may refer to the time taken for the first output voltage V1 to be lowered from the adjusted voltage level V1′ to the drop voltage level V3′ and then returned to the adjusted voltage level V1′. In the process of lowering from the adjusted voltage level V1′ to the drop voltage level V3′ and then returning to the adjusted voltage level V1′, the first output voltage V1 may pass through an intermediate level V2′. As an example, a section in which the first output voltage V1 is between the adjusted voltage level V1′ and the intermediate level V2′ is referred to as a first voltage range VP1, and a section in which the first output voltage V1 is between the intermediate level V2′ and the drop voltage level V3′ is referred to as a second voltage range VP2. According to an example, when the first output voltage V1 is in the first voltage range VP1, the sub-voltage generating circuit 163 may operate in the first operating mode. When the first output voltage V1 is in the second voltage range VP2, the sub-voltage generating circuit 163 may operate in the second operating mode. Referring to FIG. 6B, when the first output voltage V1 is in the first voltage range VP1, the sub-voltage generating circuit 163 may operate in the first operating mode during a range between the first point in time t1 and a first intermediate point in time t1′ and a range between a second intermediate point in time t1″ and the second point in time t2. When the first output voltage V1 is in the second voltage range VP2, the sub-voltage generating circuit 163 may operate in the second operating mode during a range between the first intermediate point in time t1′ and the second intermediate point in time t1″. According to an example, the intermediate level V2′ value may be determined by, but is not limited to, a value input to the comparator included in the monitoring circuit, and may also be determined as an intermediate value between the adjusted voltage level V1′ and the drop voltage level V3′.

The first operating mode may be a mode in which the feedback loop circuit in FIG. 5 is perfectly formed and operates. The second operating mode may be a mode in which the feedback loop circuit in FIG. 5 operates without being perfectly formed. When the feedback loop circuit operates without being perfectly formed, the feedback loop circuit included in the sub-voltage generating circuit may not operate, and the second output voltage Vout may be output by the first output voltage V1 that is applied.

According to a comparative example, when the load circuit is connected and drop occurs, the second output voltage is raised only by using the feedback loop, and thus, the amount of current for driving the feedback loop when the load circuit is connected is limited, thereby limiting the rising rate of the second output voltage. In order to increase the rising rate, the amount of current for driving the feedback loop has to be increased, but this also results in increased power consumption. Therefore, herein, the recovery time of the second output voltage Vout may be reduced by controlling the output of the sub-voltage generating circuit to be different for each range of the output voltage. According to the inventive concept, by controlling the second output voltage Vout to be output by the feedback loop circuit in the first voltage range and controlling the second output voltage Vout to be output by the first output voltage V1 in the second voltage range, voltage pumping may be performed faster and with less current consumption compared to an example of controlling the output of a sub-voltage generating circuit using only the feedback loop circuit.

Referring to the lower drawing of FIG. 6B, the solid line indicates the result of controlling the output of the sub-voltage generating circuit using only the feedback loop circuit according to the comparative example, and the dashed line indicates the result of controlling the output of the sub-voltage generating circuit by appropriately adjusting the output of the feedback loop circuit and the first output voltage according to an embodiment.

It can be seen that a recovery time P3 according to the result indicated by the dashed line is reduced compared to the recovery time P2 according to the result indicated by the solid line. Accordingly, the recovery time is reduced, enabling fast rising, and the word line setup time may also be reduced accordingly, enabling efficient operation.

FIG. 7 is a diagram illustrating a current flow in the sub-voltage generating circuit 163a according to the first operating mode.

The first operating mode may refer to an embodiment in which the feedback loop of the sub-voltage generating circuit 163a is perfectly formed. In the first operating mode, the first switch SW0 and the fourth switch SW3 may be turned on and connected, and the second switch SW1 and the third switch SW2 may be turned off and opened. By turning on the first switch SW0, the current source IA may be electrically connected to the third transistor M3. By turning on the fourth switch SW3, the fourth resistor R4 may be electrically connected to the fifth resistor R5. In FIG. 7, a portion indicated by the bold line indicate paths through which current may flow in the first operating mode.

Accordingly, the current generated from the current source IA may be copied and flow equally to the first transistor M1 and the fifth transistor M5. In addition, the pass transistor PASS TR may be turned on, and the feedback voltage VFB1 based on the fourth resistor R4 and the fifth resistor R5 of the feedback loop circuit may be input to the third comparator OP3, so that a comparison output may be input to the gate of the second transistor M2, and thus, a perfect feedback loop may be formed. Here, because the second output voltage Vout may be affected by the first current I1, the second current I2, and the third current I3, the current consumption in the first operating mode may be greater than the current consumption in the second operating mode to be described below.

FIG. 8 is a diagram illustrating a current flow in the sub-voltage generating circuit according to the second operating mode.

The second operating mode may refer to an embodiment in which the feedback loop is not perfectly formed. In the second operating mode, the first switch SW0 and the fourth switch SW3 may be turned off and opened, and the second switch SW1 and the third switch SW2 may be turned on and connected. By turning off the first switch SW0 and turning on the second switch SW1, the current mirror circuit connected to the current source IA may not operate. By turning on the third switch SW2, the output from the third comparator OP3 may flow toward the third switch SW2. In addition, because the fourth switch SW3 is turned off, the third comparator OP3 may not operate normally. In the second operating mode, by driving the pass transistor PASS TR in conjunction with the rising of the first output voltage V1, a fast rising may be induced, and the OFF state of the first transistor M1 and the second transistor M2 may be induced. A portion indicated by the bold line in FIG. 8 indicates a path through which current may flow in the second operating mode.

In the second operating mode, the feedback loop circuit may not actually operate, and the first output voltage V1 output from the charge pump 161a may be transmitted through the fifth transistor M5 and the pass transistor PASS TR, so that the first output voltage V1 output from the charge pump 161a may be transmitted to the output node of the sub-voltage generating circuit 163a through the pass transistor PASS TR. For example, the pass transistor PASS TR may output the second output voltage Vout based on a second current I2 flowing through the fifth transistor M5. In addition, because some current paths are blocked due to the OFF states of the first transistor M1, the second transistor M2, and the fourth switch SW3, the current consumption may be reduced compared to the first operating mode.

In the second operating mode, because the second output voltage Vout is affected only by the second current I2 and the third current I3, the current consumption is less than that in the first operating mode, and by using the first output voltage V1 that is higher than the output voltage of the sub-voltage generating circuit, the drop voltage may be recovered faster, thereby ensuring faster rising. In addition, the setup time may also be reduced accordingly, which may reduce overall power consumption.

Therefore, by alternately applying the first operating mode and the second operating mode according to the voltage range, it is possible to secure a fast recovery time of the second output voltage Vout, while saving current consumption. Hereinafter, various circuit embodiments of the sub-voltage generating circuit 163 and the monitoring circuit 164 are disclosed.

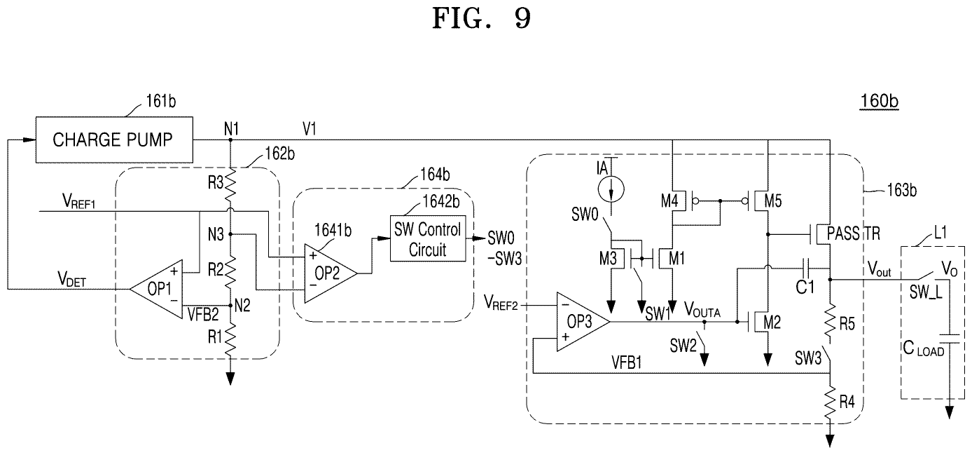

FIG. 9 illustrates a circuit of a voltage generator 160b according to an embodiment.

Referring to FIG. 9, the voltage generator 160b may include a charge pump 161b, a regulator 162b, a sub-voltage generating circuit 163b, and a monitoring circuit 164b. A configuration of the charge pump 161b corresponds to the charge pump 161 in FIG. 3, and a configuration of the sub-voltage generating circuit 163b corresponds to the configuration of the sub-voltage generating circuit 163a described above with reference to FIG. 5, so a redundant description thereof is omitted.

The regulator 162b may include a first comparator OP1, a first resistor R1, a second resistor R2, and a third resistor R3. The first comparator OP1 may include a first input terminal to which a reference voltage V_{REF1} is applied and a second input terminal to which a feedback voltage VFB2 is applied. The first comparator OP1 may compare a potential difference between the reference voltage V_{REF1} and the feedback voltage VFB2. The first comparator OP1 may output a voltage V_{DET} corresponding to the compared potential difference. The regulator 162b may include the first, second, and third resistors R1, R2, and R3 for feedback, and the first resistor R1, the second resistor R2, and the third resistor R3 may be connected in series. One end of the third resistor R3 may be connected to a node N1, and the other end of the third resistor R3 may be connected to the second resistor R2. The other end of the second resistor R2 may be connected to the first resistor R1. A voltage of a node N2 between the second resistor R2 and the first resistor R1 may be applied to the first comparator OP1 as a feedback voltage VFB2. The first output voltage V1, which is the voltage of node N1, may be distributed according to the ratio of the first, second, and third resistors R1, R2, and R3.

The monitoring circuit 164b may include a voltage monitoring circuit 1641b and a switch control circuit 1642b. As an example, the voltage monitoring circuit 1641b may include a second comparator OP2. The reference voltage V_{REF1} may be applied to a first input terminal of the second comparator OP2, and a voltage of a node N3 between the second resistor R2 and the third resistor R3 may be applied to a second input terminal of the second comparator OP2. The second comparator OP2 may compare the difference in the ratio of the first, second, and third resistors R1, R2, and R3 of the first output voltage V1 with the reference voltage VREF1 and output a result, and the switch control circuit 1642b may receive a result of the comparison, determine whether the first output voltage V1 drops, and control the first switch SW0, the second switch SW1, the third switch SW2, and the fourth switch SW3 to one of the first operating mode or the second operating mode accordingly. According to an example, when the first output voltage V1 is in the first voltage range VP1, the switch control circuit 1642b may control the first switch SW0 and the fourth switch SW3 to be turned on and the second switch SW1 and the third switch SW2 to be turn off so that the sub-voltage generating circuit may operate in the first operating mode. According to an example, when the first output voltage V1 is in the second voltage range VP2, the switch control circuit 1642b may control the second switch SW1 and the third switch SW2 to be turned on and the first switch SW0 and the fourth switch SW3 to be turned off so that the sub-voltage generating circuit may operate in the second operating mode.

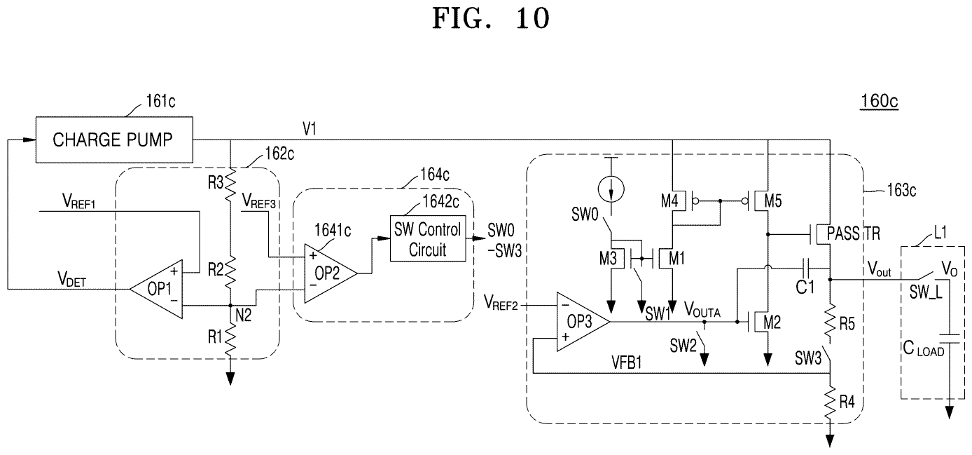

FIG. 10 illustrates a circuit of a voltage generator 160c according to an embodiment.

Referring to FIG. 10, the voltage generator 160c may include a charge pump 161c, a regulator 162c, a sub-voltage generating circuit 163c, and a monitoring circuit 164c. A configuration of the charge pump 161c corresponds to the charge pump 161 in FIG. 3, a configuration of the regulator 162c corresponds to the regulator 162b in FIG. 9, and a configuration of the sub-voltage generating circuit 163c corresponds to the configuration of the sub-voltage generating circuit 163a described above with reference to FIG. 5, so a redundant description thereof is omitted.

The monitoring circuit 164c may include a voltage monitoring circuit 1641c and a switch control circuit 1642c. As an example, the voltage monitoring circuit 1641c may include a second comparator OP2. The voltage monitoring circuit 1641c of FIG. 10 may different from the voltage monitoring circuit 1641b of FIG. 9 in that a third reference voltage V_{REF3} may be applied to the first input terminal of the second comparator OP2 included in the voltage monitoring circuit 1641c of FIG. 10 and a voltage from the node N2 between the second resistor R2 and the first resistor R1 may be applied to the second input terminal of the second comparator OP2 included in the voltage monitoring circuit 1641c. Through this, an intermediate level V2′ may be determined based on a different criterion than the voltage monitoring circuit 1641b in FIG. 9, and the sub-voltage generating circuit 163c may be controlled to operate in one of the first operating mode or the second operating mode according to the determined intermediate level V2′.

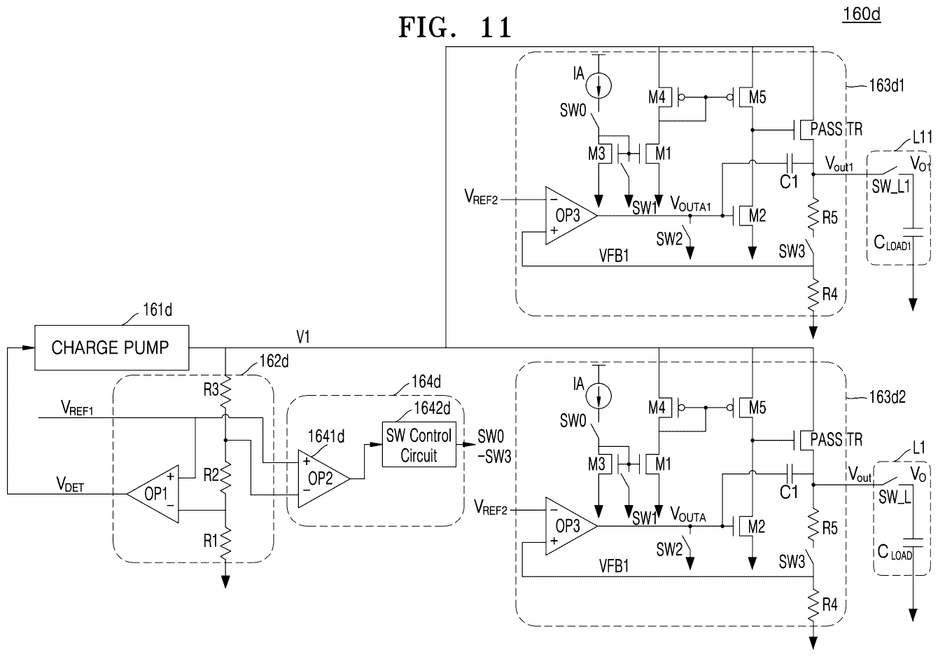

FIG. 11 illustrates a circuit of a voltage generator 160d according to an embodiment.

Referring to FIG. 11, the voltage generator 160d may include a charge pump 161d, a regulator 162d, a first sub-voltage generating circuit 163d1, a second sub-voltage generating circuit 163d2, and a monitoring circuit 164d. A configuration of the charge pump 161d corresponds to the charge pump 161 in FIG. 3, a configuration of the regulator 162d corresponds to the regulator 162b in FIG. 9, and a configuration of the monitoring circuit 164d corresponds to the monitoring circuit 164b in FIG. 9, so a redundant description thereof is omitted.

Referring to FIG. 11, the first sub-voltage generating circuit 163d1 may be connected in parallel to the second sub-voltage generating circuit 163d2. For example, the first sub-voltage generating circuit 163d1 and the second sub-voltage generating circuit 163d2 may receive the adjusted first output voltage V1 from the regulator 162d and the charge pump 161d. The configuration of each of the first sub-voltage generating circuit 163d1 and the second sub-voltage generating circuit 163d2 corresponds to the configuration of the sub-voltage generating circuit 163a described above with reference to FIG. 5, so a redundant description thereof is omitted.

Referring to FIG. 11, a load circuit L11 may be additionally connected to an output node of the first sub-voltage generating circuit 163d1. The load circuit L11 may include a sixth switch SW_L1 and a load capacitor C_{LOAD1}.

According to the embodiment of FIG. 11, the sub-voltage generating circuit may be provided as two or more sub-voltage generating circuits, and when there are a plurality of sub-voltage generating circuits, the second output voltages of the sub-voltage generating circuits may also be plural. In this case, the first output voltage V1 may be monitored using the monitoring circuit 164d, and each of the first sub-voltage generating circuit 163d1 and the second sub-voltage generating circuit 163d2 may be controlled to one of the first operating mode or the second operating mode based on a monitoring result. The switch control circuit 1642d included in the monitoring circuit 164d may control each of the plurality of switches included in the first sub-voltage generating circuit 163d1 and the plurality of switches included in the second sub-voltage generating circuit 163d2.

It should be noted that the circuit configuration of each component included in the voltage generator described above with reference to FIGS. 9 to 11 may be an example, and some of circuit configurations may be changed and applied within the scope that may achieve the purpose of the invention described above. According to an embodiment, the configuration of the regulator 162d may be applied as another circuit structure capable of regulating the voltage from the charge pump 161d, and the configuration of the monitoring circuit 164d may be applied as another circuit structure capable of checking the value of the first output voltage V1 in real time, in addition to a comparator.

The voltage generator 160d according to the inventive concept may operate, while reducing the amount of current compared to the comparative example by controlling the sub-voltage generating circuit, and when the voltage generator is configured by further reducing the number of sub-voltage generating circuits, the amount of current may be further reduced, which may be more advantageous in terms of hardware.

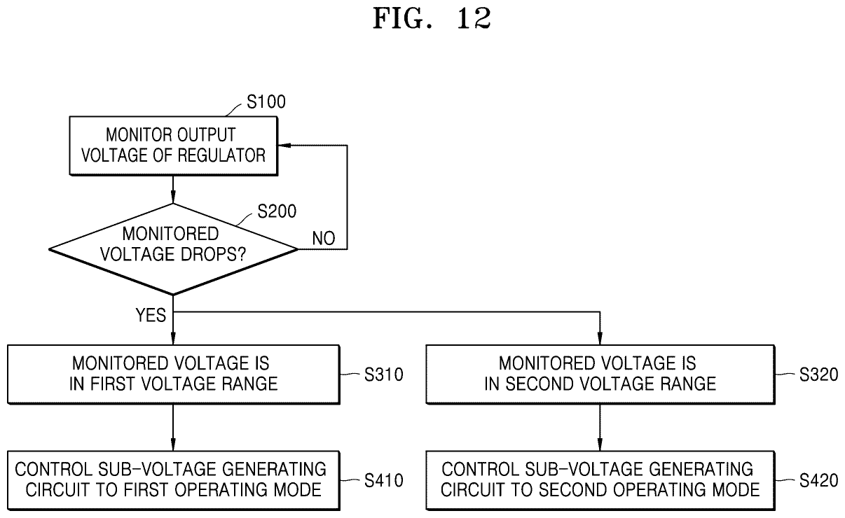

FIG. 12 is a flowchart illustrating an operating method of a memory device according to an embodiment.

Referring to FIG. 12, the operating method of a memory device according to an example may be a method of controlling a voltage applied to a memory cell array. According to an example, the operating method of the memory device may be a method of controlling the output voltage from the voltage generator 160 of FIG. 2.

Referring to operation S100, the monitoring circuit included in the voltage generator may monitor the output voltage of the regulator included in the voltage generator.

Referring to operation S200, the monitoring circuit may monitor the output voltage from the regulator to determine whether the monitored voltage drops. Whether the monitored voltage drops may be determined based on a value of a feedback voltage input to the comparator included in the monitoring circuit. Alternatively, a voltage value for determining drop may be previously determined based on an output voltage level of the regulator, and whether the monitored voltage drops may be determined based on that value.

If it is determined that the monitored voltage does not drop (NO) in operation S200, the output voltage of the regulator may be continuously monitored.

If it is determined that the monitored voltage drops (YES) in operation S200, whether the monitored voltage is in the first voltage range or the second voltage range may be determined. For example, if the monitored voltage is between a level of an adjusted output voltage and an intermediate level, the monitored voltage may be determined to be in the first voltage range, and if the monitored voltage is between the intermediate level and a drop voltage level lower than the intermediate level, the monitored voltage may be determined to be in the second voltage range.

When the monitored voltage is in the first voltage range in operation S310, the sub-voltage generating circuit may be controlled to the first operating mode in operation S410. The first operating mode may be a mode in which the feedback loop included in the sub-voltage generating circuit may be controlled to operate perfectly, so that the second output voltage is output by the feedback loop.

When the monitored voltage is in the second voltage range in operation S320, the sub-voltage generating circuit may be controlled to the second operating mode in operation S420. In the second operating mode, the feedback loop included in the sub-voltage generating circuit may be controlled not to operate perfectly, so that the second output voltage is output in conjunction with the output voltage of the regulator. According to an example, in each of operations S410 and S420, whether to turn on a plurality of switches included in the sub-voltage generating circuit may be determined to be different depending on each operating mode.

Herein, by controlling the sub-voltage generating circuit to one of the first operating mode or the second operating mode depending on the level of the first output voltage, a faster rising of the second output voltage may be secured and also the driving current may be reduced, thereby reducing power consumption, compared to a comparative example in which the output of the sub-voltage generating circuit is controlled only in the first operating mode.

While the inventive concept has been particularly shown and described with reference to embodiments thereof, it will be understood that various changes in form and details may be made therein without departing from the spirit and scope of the present invention as set forth in the following claims.

What is claimed is:

1. A memory device comprising:
a memory cell region in which a plurality of memory cells electrically connected to a plurality of word lines are arranged; and
a peripheral circuit region in which peripheral circuits configured to control the plurality of memory cells are arranged,
wherein the peripheral circuit region includes a voltage generator configured to generate an operating voltage applied to the plurality of word lines, and
wherein the voltage generator includes:
a regulator configured to adjust and output a first output voltage having a first level on a first node;
a sub-voltage generating circuit configured to generate the operating voltage on an output node based on the first output voltage; and
a monitoring circuit configured to:
monitor the first output voltage, and
control the sub-voltage generating circuit based on a result of the monitoring.

2. The memory device of claim 1, wherein the monitoring circuit is configured to monitor whether the first output voltage drops.

3. The memory device of claim 2, wherein the sub-voltage generating circuit includes:
a current generating circuit configured to receive the first output voltage and output the operating voltage on the output node based on the first output voltage; and
a feedback loop circuit connected to the current generating circuit, and
wherein the sub-voltage generating circuit is configured to operate in one of a first operating mode and a second operating mode different from the first operating mode based on a voltage range of the first output voltage.

4. The memory device of claim 3, wherein the sub-voltage generating circuit is configured to operate in the first operating mode in the voltage range in which a voltage level of the first output voltage is between the first level and an intermediate level lower than the first level, and
wherein, in the first operating mode, the current generating circuit is configured to generate and copy current within the sub-voltage generating circuit and output the operating voltage based on the current when the feedback loop circuit is operated based on the operating voltage.

5. The memory device of claim 4, wherein the current generating circuit includes:
a current source configured to flow a source current;
a first switch connected between the current source and a third transistor configured to flow the source current by turning on the first switch; and
a pass transistor configured to flow a third current based on the source current, and output the operating voltage based on the third current,
wherein the feedback loop circuit includes:
a second transistor configured to flow a second current based on the source current;
a first resister including a first end connected to the output node of the sub-voltage generating circuit, and a second end;
a third switch connected between the second end of the first resister and a second resistor; and
a comparator configured to compare a reference voltage with a feedback voltage from a node connected to the second end of the first resister and the second resistor when the third switch is turned on, and output a comparison result to a gate of the second transistor.

6. The memory device of claim 3, wherein the sub-voltage generating circuit is configured to operate in the second operating mode in the voltage range in which a voltage level of the first output voltage is between an intermediate level lower than the first level and a drop voltage level lower than the intermediate level, and
wherein, in the second operating mode, the current generating circuit is configured to output the operating voltage based on the first output voltage when the feedback loop circuit is not operated.

7. The memory device of claim 6, wherein the current generating circuit includes:
a fifth transistor including a first end connected to the first node and configured to flow a second current; and
a pass transistor including a first end connected to the first node and configured to flow a third current based on the second current, and output the operating voltage based on the third current.

8. A voltage generator comprising:
a regulator configured to generate a first output voltage having a first level that is adjusted;
a sub-voltage generating circuit configured to generate an operating voltage based on the first output voltage; and
a monitoring circuit configured to:
monitor a voltage level of the first output voltage, and
control the sub-voltage generating circuit based on a result of the monitoring,
wherein the sub-voltage generating circuit is configured to operate in one of a first operating mode and a second operating mode different from the first operating mode based on the voltage level of the first output voltage.

9. The voltage generator of claim 8, wherein the monitoring circuit is configured to monitor a voltage range in which the first output voltage drops.

10. The voltage generator of claim 9, wherein the sub-voltage generating circuit includes:
a current generating circuit configured to receive the first output voltage and output the operating voltage on an output node of the sub-voltage generating circuit based on the first output voltage; and
a feedback loop circuit connected to the current generating circuit.

11. The voltage generator of claim 10, wherein the sub-voltage generating circuit is configured to operate:
in the first operating mode in the voltage range in which the voltage level of the first output voltage is between the first level and an intermediate level lower than the first level, and
in the second operating mode in the voltage range in which the voltage level of the first output voltage is between the intermediate level and a drop voltage level lower than the intermediate level.

12. The voltage generator of claim 11, wherein the sub-voltage generating circuit includes first to fourth switches configured to control the current generating circuit and the feedback loop circuit,
wherein, in the first operating mode, the current generating circuit and the feedback loop circuit are configured to operate normally by turning on the first switch and the fourth switch, and turning off the second switch and the third switch, and
wherein, in the second operating mode, the current generating circuit and the feedback loop circuit are not configured to operate normally by turning on the second switch and the third switch and turning off the first switch and the fourth switch.

13. The voltage generator of claim 11, wherein, in the first operating mode, the current generating circuit is configured to generate and copy current based on the first output voltage and output the operating voltage based on the copied current when the feedback loop circuit is configured to operate as a feedback loop.

14. The voltage generator of claim 11, wherein, in the second operating mode, the current generating circuit is configured to output the operating voltage based on the first output voltage when the feedback loop circuit is not configured to operate as a feedback loop.

15. An operating method of a memory device including a memory cell array having a plurality of memory cells connected to a plurality of word lines, a regulator configured to generate a first output voltage having a first level that is adjusted, and a sub-voltage generating circuit including a current generating circuit and a feedback loop circuit and configured to generate an operating voltage applied to the plurality of word lines based on the first output voltage, the operating method comprising:
monitoring the first output voltage adjusted by the regulator;
determining whether the monitored voltage has dropped;
determining an operating mode of the sub-voltage generating circuit based on a voltage range of the monitored voltage; and
outputting the operating voltage from the current generating circuit to the plurality of word lines based on the first output voltage,
wherein the voltage range is between the first level and a drop level lower than the first level.

16. The operating method of claim 15, wherein, the determining of the operating mode includes:
determining a first operating mode when the voltage range is between the first level and an intermediate level lower than the first level and higher than the drop level; and
determining a second operating mode when the voltage range is between the intermediate level and the drop level.

17. The operating method of claim 16, wherein, in the first operating mode, the outputting of the operating voltage includes generating the operating voltage from the current generating circuit based on forming a feedback loop in the feedback loop circuit.

18. The operating method of claim 17, wherein, in the first operating mode, the outputting of the operating voltage includes generating and copying a current in the current generating circuit and forming the feedback loop in the feedback loop circuit based on the copied current.

19. The operating method of claim 16, wherein, in the second operating mode, the outputting of the operating voltage includes generating the operating voltage from the current generating circuit when the feedback loop circuit is not configured to form a feedback loop.

20. The operating method of claim 15, wherein the determining of the operating mode includes differently determining whether to turn on or turn off a plurality of switches included in the sub-voltage generating circuit according to the operating mode.
